(19) United States
(12) Patent Application Publication
(10) Pub. No.: US 2014/0303912 A1
(43) Pub. Date: Oct. 9, 2014

(54) SYSTEM AND METHOD FOR THE AUTOMATIC DETERMINATION OF CRITICAL PARAMETRIC ELECTRICAL TEST PARAMETERS FOR INLINE YIELD MONITORING

(71) Applicant: KLA-Tencor Corporation, Milpitas, CA (US)

(72) Inventors: Saibal Banerjee, Fremont, CA (US); Sonu Maheshwary, San Ramon, CA (US); John Charles Robinson, Austin, TX (US); Dale Legband, Pflugerville, TX (US)

(73) Assignee: KLA-Tencor Corporation, Milpitas, CA (US)

(21) Appl. No.: 14/242,528

(22) Filed: Apr. 1, 2014

Related U.S. Application Data
(60) Provisional application No. 61/809,407, filed on Apr. 7, 2013.

(51) Int. Cl. G01R 31/26

(52) U.S. Cl. CPC G01R 31/2601
USPC 702/57

(57) ABSTRACT

Inline yield monitoring may include the use of one or more modules of algorithmic software. Inline yield monitoring may include the use of two related algorithmic software modules such as a learning and a prediction module. The learning module may learn critical PET (parametric electrical test) parameters from data of probe electrical test yields and PET attribute values. The critical PET parameters may best separate outliers and inliers in the yield data. The prediction module may use the critical PET parameters found by the learning module to predict whether a wafer is an inlier or an outlier in a probe test classification.

### PRIORITY CLAIM

This patent claims priority to U.S. Provisional Patent Application No. 61/809,407 filed Apr. 7, 2013, which is incorporated by reference in its entirety.

### BACKGROUND

1. Field of the Invention

The present invention relates to inline monitoring of die yields. More particularly, the invention relates to inline monitoring of die yields using electrical test data analysis in a semiconductor fab or foundry.

2. Description of Related Art

Currently, semiconductor fabs and foundries may employ electrical testing at two levels in order to determine their die yields. The two levels of electrical testing may include, for example, parametric electrical tests (PETs) on a wafer level and probe electrical tests (e.g., binsort) at a die level.

PETs may be performed on the wafers inside fabs or foundries during the fabrication process. PETs may be taken at various steps in the fabrication process to ensure that the quality of material being produced is suitable. PETs may be though of, for example, as electrical health inspections performed during the fabrication process. PETs may serve as an indicator of potential problems occurring during the fabrication process. PETs are typically relatively inexpensive to perform and have quick turnaround times. Because of the small cost and quick turnaround, fabs may typically perform the PETs on a large sample of wafers in a lot (but not the entire lot).

PETs, however, produce a large number of numerically valued attributes (on the order of 10,000 attributes). A small set of these attributes may be marked critical by process engineers on the basis of physics and/or historical data. Statistical process control thresholds may be set on the values of these critical attributes and all deviations from these thresholds may be monitored and tightly controlled for yield.

Given the large number of PET attributes, however, it may be a difficult engineering task to manually determine which of the attributes are critical and which are not; especially for new products during a ramp in phase when there is a smaller amount of process information. It may also be a difficult manual engineering task to set statistical process thresholds for the critical PET attributes (especially for new products during the ramp in phase). Because of the large manual task, engineers in a fab may spend an inordinate amount of time sifting through large data because of not knowing what data is important and what data is not important. Thus, such processes may be labor intensive and increase fab costs and reduce fab efficiency. Additionally, because of these issues, fab managers may not get actionable insights needed to drive tactical and strategic decisions to effectively manage fab metrics and maintain profitability.

Probe electrical tests (e.g., binsort) are another set of electrical measurements performed on the final wafer on a per die basis. Probe electrical tests produce the die yield of the wafer, defined as a percentage of the number of good dies on the wafer to the total number of dies on that wafer. This die yield result from the probe electrical tests may be used by fabs and foundries as their final yield statistic and overall measure of product quality. Probe electrical tests, however, are not very useful in yield monitoring because the tests are performed after the wafer is finished processing. Additionally, most probe electrical tests occur off-site as fabs and foundries do not typically have the probe testing equipment. Thus, by the time a wafer has been probe tested, it is a finished product and little or no corrective action may be taken to remedy any defects on the wafer itself. In addition, any insight gained into the root cause of yield problems (e.g., yield loss) from the probe electrical tests has a long cycle time and during this cycle time many more wafers or lots may have been processed using the same defective process, which may be a financial loss for the fab. Additional costs are also incurred due to the cost of probe electrical tests. Probe electrical tests typically cost 5 to 10 times more than PETs.

### SUMMARY

In certain embodiments, a computer implemented method includes receiving, at a computer processor, input of yield value data from a database of yield values for probe electrical tests performed on a set of semiconductor wafers produced using a semiconductor process. Input of parametric electrical test attribute value data is received at the computer processor from a database of parametric electrical test attribute values for parametric electrical tests performed on the set of semiconductor wafers. The computer processor may classify the received yield value data into an inlier class and an outlier class. The computer processor may assess one or more critical parametric electrical test attributes based on the inlier class and the outlier class of the received yield value data and the received parametric electrical test attribute value data. The computer processor may assess one or more statistical process control thresholds corresponding to one or more of the critical parametric electrical test attributes. The statistical process control thresholds may be process control thresholds for the semiconductor process. The computer processor may generate a database of critical parametric electrical test parameters. The critical parametric electrical test parameters may include critical parametric electrical test attributes and their corresponding statistical process control thresholds.

In certain embodiments, a computer implemented method includes receiving, at a computer processor, input of parametric electrical test attribute value data from a database of parametric electrical test attribute values for parametric electrical tests performed on a set of semiconductor wafers produced using a semiconductor process. The computer processor may receive input of critical parametric electrical test parameters from a database of critical parametric electrical test parameters. The critical parametric electrical test parameters may include critical parametric electrical test attributes and their corresponding statistical process control thresholds for the semiconductor process. The computer processor may assess a probe electrical test classification of one or more semiconductor wafers being tested with a parametric electrical test. The assessment may be based on the received parametric electrical test attribute value data and the received critical parametric electrical test parameters. The probe electrical test classification may include classifying a semiconductor wafer in either an inlier class or an outlier class of probe electrical test yield data. The computer processor may generate a database of probe electrical test classifications using the assessed probe electrical test classifications.

### BRIEF DESCRIPTION OF THE DRAWINGS

Features and advantages of the methods and apparatus of the present invention will be more fully appreciated by reference to the following detailed description of presently preferred but nonetheless illustrative embodiments in accordance with the present invention when taken in conjunction with the accompanying drawings in which:

FIG. 1 depicts an embodiment of a hierarchy for application of inline yield monitoring.

FIG. 2 depicts a flowchart of an embodiment of a learning module process.

FIG. 3 depicts an embodiment of a plot of yield value data shown as number of wafers versus yield (in terms of yield percentage).

FIG. 4 depicts a representation of an embodiment of mutual information statistic based attribute ranking to determine critical PET attributes.

FIG. 5 depicts balls representing the PET attribute sorted based on attribute value.

FIG. 6 depicts a flowchart of an embodiment of a prediction module process.

FIG. 7 depicts an example of a plot of highest ranking PET attribute values versus probe electrical test yield for a (formerly) non-critical attribute.

While the invention is susceptible to various modifications and alternative forms, specific embodiments thereof are shown by way of example in the drawings and will herein be described in detail. The drawings may not be to scale. It should be understood that the drawings and detailed description thereto are not intended to limit the invention to the particular form disclosed, but to the contrary, the intention is to cover all modifications, equivalents and alternatives falling within the spirit and scope of the present invention as defined by the appended claims.

### DETAILED DESCRIPTION OF EMBODIMENTS

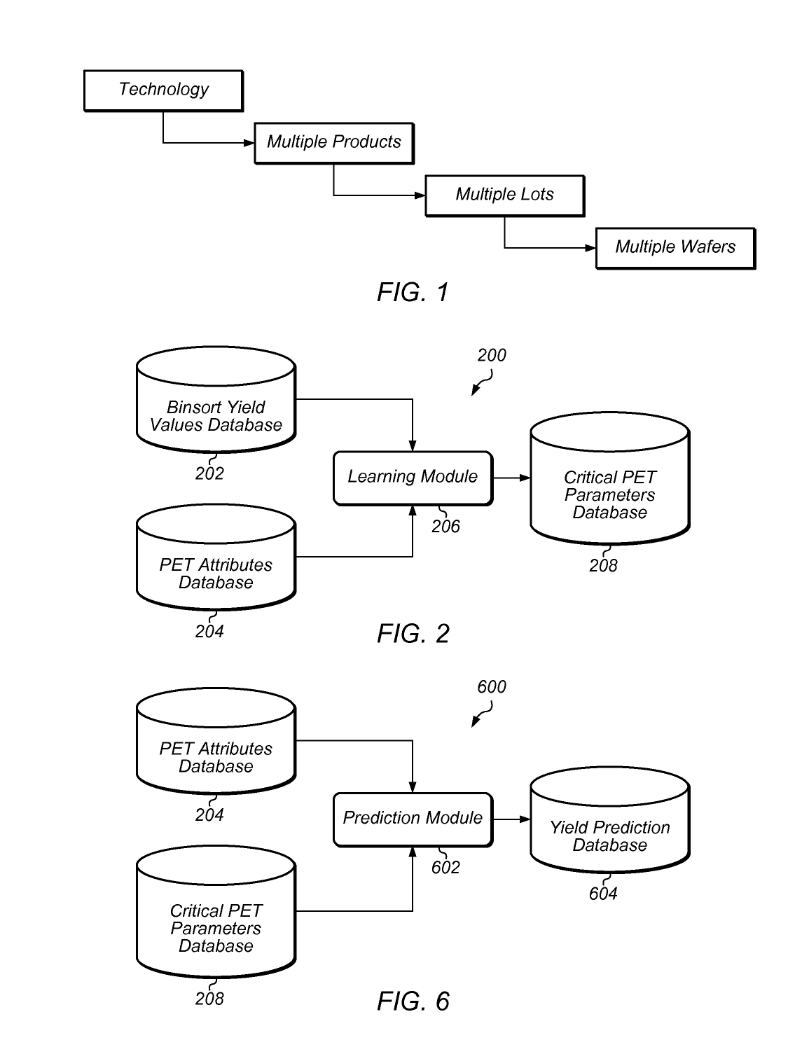

Inline yield monitoring, as disclosed herein, describes monitoring of parameters and/or attributes during semiconductor processing of semiconductor wafers to produce desired and/or maximized yields. In certain embodiments, inline yield monitoring is applied to a single technology (e.g., a single semiconductor process operated in a fab or foundry) or on multiple products of the same technology by grouping similar products. In some embodiments, inline yield monitoring is applied to multiple lots or multiple wafers. FIG. 1 depicts an embodiment of a hierarchy for application of inline yield monitoring as disclosed herein.

In certain embodiments, inline yield monitoring includes the use of one or more modules of algorithmic software. The algorithmic software modules may be related. In certain embodiments, inline yield monitoring includes the use of two related algorithmic software modules. For example, inline yield monitoring may include a learning and a prediction module, which are related algorithmic software modules.

FIG. 2 depicts a flowchart of an embodiment of learning module process 200. Process 200 may be used, for example to assess (“learn”) critical PET (parametric electrical test) parameters that best separate outliers in yield data from inliners in the yield data (e.g., normal yield data), where the yield data is found using probe electrical tests.

In certain embodiments, database 202 is a database of yield values for probe electrical tests (e.g., binsort yields) performed on a set of semiconductor wafers. The semiconductor wafers may be produced using a semiconductor process. In certain embodiments, database 204 is a database of parametric electrical test (PET) attribute values for parametric electrical tests performed on the set of semiconductor wafers. The PET tests may be performed on the same set of semiconductor wafers as the probe electrical tests. In some embodiments, the database of PET attribute values includes at least some missing attribute values. The missing attribute values may be the result of not all PETs being performed on all the semiconductor wafers in the set.

In certain embodiments, learning module 206 receives input from database 202 and/or database 204. Learning module 206 may, for example, receive input of yield value data from database 202 and receive input of PET attribute value data from database 204.

In certain embodiments, learning module 206 automatically determines (e.g., automatically processes the data to determine) an inlier class and an outlier class in the yield value data input from database 202. Thus, learning module 206 may classify the yield value data into the inlier class and the outlier class. In certain embodiments, an unsupervised classification algorithm classifies the yield value data into the inlier class and the outlier class.

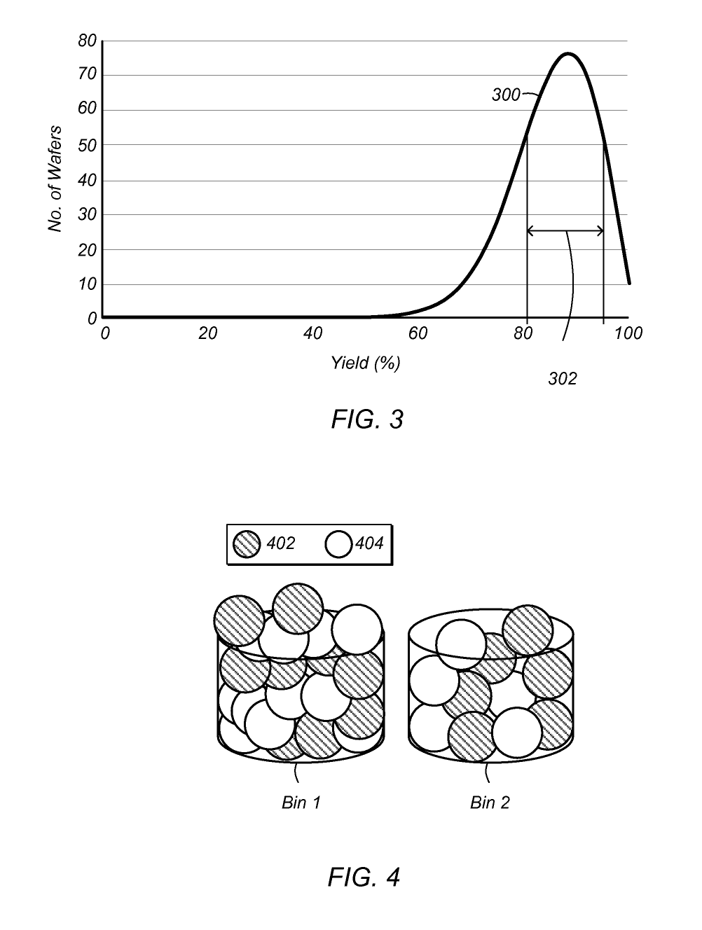

In certain embodiments, learning module 206, shown in FIG. 2, sorts the received yield value data as a distribution. For example, the distribution of yield value data may be sorted by yield percentage. FIG. 3 depicts an embodiment of a plot of yield value data shown as number of wafers versus yield (in terms of yield percentage). Data points for plot 300 may be produced using one or more probe electrical tests on the set of semiconductor wafers.

In order to classify the yield value data, learning module 206, shown in FIG. 2, may assess quartile ranges in the distribution of yield value data (e.g., the distribution shown by plot 300 in FIG. 3). Assessing the quartile ranges may include assessing an interquartile range of the yield value data. In some embodiments, the interquartile range is defined by the thinnest pair of lines containing 50% of the data points between the lines. Line pair 302, shown in FIG. 3, is an example of a line pair that contains 50% of the data points of plot 300 between the lines. In certain embodiments, after the interquartile range is defined, the mean and standard deviation of the data points in the interquartile range (e.g., data points enclosed by line pair 302) is assessed (e.g., assessed by learning module 206). In certain embodiments, the mean and standard deviation are assessed using a Gaussian fit of the data points (e.g., a Gaussian fit of the head of the yield value distribution).

After the mean and standard deviation are assessed, learning module 206 may assign the outlier class (the tail of the yield value data distribution) to the yield value data (e.g., plot 300). In certain embodiments, the outlier class is assigned as being below (the first quartile−a selected value×the interquartile range) or above (the third quartile+the selected value×the interquartile range). In some embodiments, the selected value for the outlier class assignment is determined based on the mean and standard deviation found for the interquartile range of the yield value data. In some embodiments, outliers do not exist in the yield value data (e.g., plot 300). If, however, outliers do exist, they would fall on the tail of the yield value data distribution. The inlier class (the head of the yield value distribution) may be assigned as being data values not assigned to the outlier class (e.g., data values that fall within the boundaries defining the outlier class).

Following classification of the yield value data, learning module 206, shown in FIG. 2, may use the classification of the yield value data to assess (e.g., determine) one or more critical PET attributes. In certain embodiments, the critical PET attributes are assessed based on the inlier class and the outlier class of the received yield value data and the received PET attribute value data. In certain embodiments, the critical PET attributes are PET test attributes that provide desired separation of the outlier class and the inlier class (e.g., the critical PET attributes are the PET attributes selected to best separate the outlier class and the inlier class of the yield value data).

In certain embodiments, a supervised classification algorithm assess the critical PET attributes. The supervised classification algorithm may include using the classification of the outlier class and the inlier class as the supervised classes and using the PET attribute value data as features of the supervised classes. Subsequently, a figure of merit on the classification capability may be produced with a subset of these features.

In some embodiments, the figure of merit is a mutual information statistic based attribute ranking. FIG. 4 depicts a representation of an embodiment of mutual information statistic based attribute ranking to determine critical PET attributes. For the mutual information statistic based attribute ranking, as shown in FIG. 4, each PET attribute (represented by the balls) is given a head (the inlier class represented by ball 402) or tail (the outlier class represented by ball 404) designation following classification of yield value data. Additionally, each PET attribute is assigned to a bin (e.g., bin 1 or bin 2) based on the probe electrical test results (e.g., binsort results) of wafers tested for the PET attributes. For the PET attributes, the bin counts (frequencies) may be represented by X while the yield classification (e.g., head or tail) may be represented by Y. Thus, I(X; Y) may be the mutual information statistic between X and Y for the PET attributes.

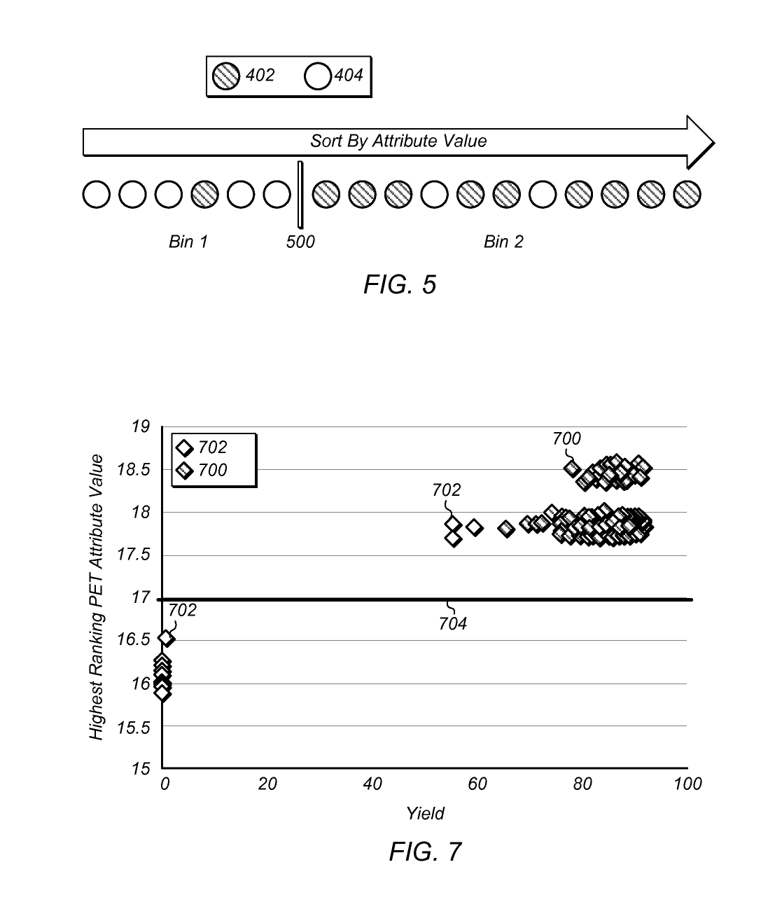

For each PET attribute, balls representing the PET attribute may be sorted based on attribute value, as shown in FIG. 5. As shown in FIG. 5, a single cut (e.g., line 500) may be found that best separates balls 402 from balls 404 into 2 bins (e.g., bins 1 and 2). In certain embodiments, the best single cut is the cut that maximizes the mutual information statistic rating for each attribute. Following determination of the maximized mutual information statistic rating for each PET attribute, the PET attributes may be ranked corresponding to their maximized mutual information statistic ratings. A selected number of PET attributes with the highest mutual information statistic ratings may then be chosen as critical PET attributes. Thus, a large mass of PET attributes is reduced (e.g., automatically trimmed) to a small, best set of PET attributes based on the criticality of the PET attributes to probe electrical test yield.

In some embodiments, as described above, the PET attribute value data includes at least some missing attribute values. Learning module 206, shown in FIG. 2, may still, however, assess the critical PET attributes given the missing attribute values. For example, using the mutual information statistic based ranking, a proportion of non-missing attribute values may be used to rank the PET attributes. Given 2 PET attributes A₁ and A₂ without any missing values, if X₁ and X₂ are their best 2 bin allocations for the given Y yield classification in terms of the mutual information statistic, then A₁≧A₂ if and only if I(X₁; Y)≧I(X₂; Y). For 2 PET attributes A₁ and A₂ with any missing values, if X₁ and X₂ are their best 2 bin allocations for the given Y yield classification in terms of the mutual information statistic with missing attributes not considered in the allocation, then A₁≧A₂ if and only if p₁I(X₁; Y)≧p₂I(X₂;Y); where pᵢ is the proportion of non-missing attribute values for Aᵢ.

In some embodiments, process 200 identifies selected PET attributes as critical that may not be identified as critical PET attributes using current criticality identification methods (e.g., manual engineering methods). Process 200 may identify a (formerly) non-critical PET attribute as critical because this PET attribute has a high criticality ranking (e g , a high mutual information statistic based ranking) For example, the (now) critical attribute may provide perfect or near perfect classification between the inlier class and the outlier class.

FIG. 7 depicts an example of a plot of highest ranking PET attribute values versus probe electrical test yield for a (formerly) non-critical attribute. Inlier class (head) attributes are identified as data 700 while outlier class (tail) attributes are identified as data 702. Line 704 represents the cut separating the attribute values into 2 bins (e.g., the single cut found using the mutual information statistic based attribute ranking) As shown in FIG. 7, the (formerly) non-critical attribute provides nearly perfect classification between inlier class data 700 and outlier class data 702.

After assessing the critical PET attributes, learning module 206 may assess one or more statistical process control thresholds corresponding to one or more of the critical PET attributes. The statistical process control thresholds may be, for example, process control thresholds for the semiconductor process used to produce the set of semiconductor wafers. The combination of critical PET attributes and their corresponding statistical process control thresholds may be called critical PET parameters. In certain embodiments, learning module 206 generates a database of critical PET parameters. Learning module 206 may output the database of critical PET parameters to database 208, shown in FIG. 2. Thus, database 208 may be a database of critical PET parameters corresponding to database 202 and database 204 for the set of semiconductor wafers.

In certain embodiments, critical PET parameters produced using process 200 are used to indicate whether a semiconductor wafer tested using a PET test is classified in the inlier class or the outlier class. For example, parametric electrical test data for one or more semiconductor wafers may be used (e.g., received and process by a computer processor) to predict whether each wafer is classified in the inlier class or the outlier class based on the critical PET parameters. The prediction may be performed, for example, using a prediction algorithmic software module.

FIG. 6 depicts a flowchart of an embodiment of prediction module process 600. Process 600 may be used, for example to assess (“predict”) a probe electrical test classification of semiconductor wafers being tested with a PET test. Thus, process 600 may be used as a “proxy” for an actual probe electrical test process (e.g., process 600 allows PET testing results to produce classification results akin to results found using the actual probe electrical test process).

In certain embodiments, prediction module 602 receives input from database 204 and/or database 208. Prediction module 602 may, for example, receive input of PET attribute value data from database 204 and input of critical PET parameters from database 208. In certain embodiments, the PET attribute value data input from database 204 is input data different from data input into learning module 206, shown in FIG. 2. For example, PET attribute value data input into prediction module 602 may include data for an additional and/or different set of semiconductor wafers than the set of semiconductor wafers input into learning module 206.

In certain embodiments, prediction module 602 assesses (e.g., predicts) a probe electrical test classification of one or more semiconductor wafers. In some embodiments, the semiconductor wafers are being tested using a PET. The assessment may be based on the received PET value data and the received critical PET parameters. In certain embodiments, the probe electrical test classification includes classifying a semiconductor wafer in either the inlier class or the outlier class of probe electrical test yield data (e.g., the semiconductor wafer is classified according to the yield value data classes found by learning module 206).

In certain embodiments, prediction module 602 generates a database of probe electrical test classifications using the assessed probe electrical test classifications. Prediction module 602 may output the database of probe electrical test classifications to database 604. Thus, database 604 may be a database of probe electrical test classifications corresponding to database 204 and database 208 for a set of semiconductor wafers.

In some embodiments, one or more operating conditions for the semiconductor process are modified based on the assessed probe electrical test classifications, the received parametric electrical test attribute value data, and the received critical parametric electrical test parameters. In some embodiments, the operating conditions are modified after receiving input of probe electrical test classification data from database 604. Assessing probe electrical test classification data following only PET testing of semiconductor wafers during processing of the wafers allows operating conditions to be more immediately modified, which leads to higher yields as fewer wafers are processed at the undesired operating conditions. Assessing probe electrical test classification data following PET testing of semiconductor wafers may also reduce the need for probe electrical tests as only a small sample size is needed to be probed to produce the final classification data. Reducing the use of probe electrical tests may reduce expenses and/or logistical problems (e.g., problems with transport and collection of wafers). Thus, fabs and/or foundries may reduce their overall costs and find yield problems in a timelier manner

In certain embodiments, one or more process steps described herein are operated using software executable by a processor (e.g., a computer processor or an integrated circuit). For example, process 200 or process 600, shown in FIGS. 2 and 6, respectively, may have one or more steps controlled or operated using software executable by the processor. In addition, one or more modules (e.g., learning module 206 or prediction module 602) may be controlled or operated using software executable by the processor. In some embodiments, the process steps are stored as program instructions in a computer memory or a computer readable storage medium (e.g., a non-transitory computer readable storage medium) and the program instructions are executable by the processor.

It is to be understood the invention is not limited to particular systems described which may, of course, vary. It is also to be understood that the terminology used herein is for the purpose of describing particular embodiments only, and is not intended to be limiting. As used in this specification, the singular forms “a”, “an” and “the” include plural referents unless the content clearly indicates otherwise. Thus, for example, reference to “an attribute” includes a combination of two or more attributes.

Further modifications and alternative embodiments of various aspects of the invention will be apparent to those skilled in the art in view of this description. Accordingly, this description is to be construed as illustrative only and is for the purpose of teaching those skilled in the art the general manner of carrying out the invention. It is to be understood that the forms of the invention shown and described herein are to be taken as the presently preferred embodiments. Elements and materials may be substituted for those illustrated and described herein, parts and processes may be reversed, and certain features of the invention may be utilized independently, all as would be apparent to one skilled in the art after having the benefit of this description of the invention. Changes may be made in the elements described herein without departing from the spirit and scope of the invention as described in the following claims.

What is claimed is:

1. A computer implemented method, comprising:
receiving, at a computer processor, input of yield value data from a database of yield values for probe electrical tests performed on a set of semiconductor wafers produced using a semiconductor process;
receiving, at the computer processor, input of parametric electrical test attribute value data from a database of parametric electrical test attribute values for parametric electrical tests performed on the set of semiconductor wafers;
classifying, using the computer processor, the received yield value data into an inlier class and an outlier class;
assessing, using the computer processor, one or more critical parametric electrical test attributes based on the inlier class and the outlier class of the received yield value data and the received parametric electrical test attribute value data;
assessing, using the computer processor, one or more statistical process control thresholds corresponding to one or more of the critical parametric electrical test attributes, wherein the statistical process control thresholds are process control thresholds for the semiconductor process; and
generating, using the computer processor, a database of critical parametric electrical test parameters, wherein the critical parametric electrical test parameters comprise critical parametric electrical test attributes and their corresponding statistical process control thresholds.

2. The method of claim 1, further comprising classifying the received yield value data into the inlier class and the outlier class using an unsupervised classification algorithm to classify the yield value data.

3. The method of claim 1, wherein classifying the received yield value data into the inlier class and the outlier class comprises:
sorting the received yield value data as a distribution;
assessing quartile ranges of the distribution;
assessing an interquartile range of the distribution;
assessing a mean and standard deviation of the interquartile range; and
assigning the outlier class as being below (the first quartile−a selected value×the interquartile range) or above (the third quartile+the selected value×the interquartile range).

4. The method of claim 3, wherein the mean and standard deviation are found using a Gaussian fit to the inlier class yield value data.

5. The method of claim 1, wherein the one or more critical parametric electrical test attributes comprise parametric electrical test attributes that provide desired separation of the outlier class and the inlier class of the yield value data.

6. The method of claim 1, wherein the database of parametric electrical test attribute values for parametric electrical tests performed on the set of semiconductor wafers comprises at least some missing attribute values, and wherein the one or more critical parametric electrical test attributes are assessed given the missing attribute values.

7. The method of claim 1, further comprising assessing the one or more critical parametric electrical test attributes using a supervised classification algorithm.

8. The method of claim 7, wherein the supervised classification algorithm comprises:
using the classification of the outlier class and the inlier class as the supervised classes;
using the parametric electrical test attribute value data as features of the supervised classes; and
producing a figure of merit on a classification capability with a subset of the features.

9. The method of claim 1, further comprising receiving, at the computer processor, parametric electrical test data for one or more semiconductor wafers, and predicting whether each wafer is classified in the inlier class or the outlier class based on the critical parametric electrical test parameters.

10. A computer implemented method, comprising:
receiving, at a computer processor, input of parametric electrical test attribute value data from a database of parametric electrical test attribute values for parametric electrical tests performed on a set of semiconductor wafers produced using a semiconductor process;
receiving, at the computer processor, input of critical parametric electrical test parameters from a database of critical parametric electrical test parameters, wherein the critical parametric electrical test parameters comprise critical parametric electrical test attributes and their corresponding statistical process control thresholds for the semiconductor process;
assessing, using the computer processor, a probe electrical test classification of one or more semiconductor wafers being tested with a parametric electrical test, wherein the assessment is based on the received parametric electrical test attribute value data and the received critical parametric electrical test parameters, and wherein the probe electrical test classification comprises classifying a semiconductor wafer in either an inlier class or an outlier class of probe electrical test yield data; and
generating, using the computer processor, a database of probe electrical test classifications using the assessed probe electrical test classifications.

11. The method of claim 10, further comprising modifying one or more operating conditions for the semiconductor process based on the assessed probe electrical test classifications, the received parametric electrical test attribute value data, and the received critical parametric electrical test parameters.

12. The method of claim 10, further comprising receiving, at the computer processor, input of probe electrical test classification data, and modifying one or more operating conditions for the semiconductor process based on the assessed probe electrical test classifications and the received parametric electrical test attribute value data and the received critical parametric electrical test parameters.

13. The method of claim 10, wherein the inlier class and the outlier class of probe electrical test yield data are generated by:
receiving, at the computer processor, input of yield value data from a database of yield values for probe electrical tests performed on a set of semiconductor wafers produced using the semiconductor process;
receiving, at the computer processor, input of the parametric electrical test attribute value data from the database of parametric electrical test attribute values for parametric electrical tests performed on the set of semiconductor wafers; and
classifying, using the computer processor, the yield value data into the inlier class and the outlier class.

14. The method of claim 10, wherein the database of critical parametric electrical test parameters is generated by:
receiving, at the computer processor, input of yield value data from a database of yield values for probe electrical tests performed on a set of semiconductor wafers produced using the semiconductor process;
receiving, at the computer processor, input of the parametric electrical test attribute value data from the database of parametric electrical test attribute values for parametric electrical tests performed on the set of semiconductor wafers;
classifying, using the computer processor, the yield value data into the inlier class and the outlier class;
assessing, using the computer processor, one or more critical parametric electrical test attributes based on the inlier class and the outlier class of the yield value data and the parametric electrical test attribute value data;
assessing, using the computer processor, one or more statistical process control thresholds corresponding to one or more of the critical parametric electrical test attributes, wherein the statistical process control thresholds are process control thresholds for the semiconductor process; and
generating, using the computer processor, the database of critical parametric electrical test parameters.

15. A system, comprising:
a computer memory configured to store computer program instructions; and
a computer processor configured to execute the computer program instructions and to cause the system to:
receive input of yield value data from a database of yield values for probe electrical tests performed on a set of semiconductor wafers produced using a semiconductor process;
receive input of parametric electrical test attribute value data from a database of parametric electrical test attribute values for parametric electrical tests performed on the set of semiconductor wafers;
classify the received yield value data into an inlier class and an outlier class;
assess one or more critical parametric electrical test attributes based on the inlier class and the outlier class of the received yield value data and the received parametric electrical test attribute value data;
assess one or more statistical process control thresholds corresponding to one or more of the critical parametric electrical test attributes, wherein the statistical process control thresholds are process control thresholds for the semiconductor process; and
generate a database of critical parametric electrical test parameters, wherein the critical parametric electrical test parameters comprise critical parametric electrical test attributes and their corresponding statistical process control thresholds;
wherein the critical parametric electrical test parameters are used to indicate whether a semiconductor wafer tested using a parametric electrical test is classified in the inlier class or the outlier class.

16. The system of claim 15, wherein the received yield value data is classified into the inlier class and the outlier class using an unsupervised classification algorithm.

17. The system of claim 15, wherein the one or more critical parametric electrical test attributes comprise parametric electrical test attributes that provide desired separation of the outlier class and the inlier class of the yield value data.

18. The system of claim 15, wherein the one or more critical parametric electrical test attributes are assessed using a supervised classification algorithm.

19. A system, comprising:
a computer memory configured to store computer program instructions; and
a computer processor configured to execute the computer program instructions and to cause the system to:
receive input of parametric electrical test attribute value data from a database of parametric electrical test attribute values for parametric electrical tests performed on a set of semiconductor wafers produced using a semiconductor process;
receive input of critical parametric electrical test parameters from a database of critical parametric electrical test parameters, wherein the critical parametric electrical test parameters comprise critical parametric electrical test attributes and their corresponding statistical process control thresholds for the semiconductor process;
assess a probe electrical test classification of one or more semiconductor wafers being tested with a parametric electrical test, wherein the assessment is based on the received parametric electrical test attribute value data and the received critical parametric electrical test parameters, and wherein the probe electrical test classification comprises classifying a semiconductor wafer in either an inlier class or an outlier class of probe electrical test yield data; and
generate a database of probe electrical test classifications using the assessed probe electrical test classifications.

20. The system of claim 19, wherein the computer processor further causes the system to:
receive input of yield value data from a database of yield values for probe electrical tests performed on a set of semiconductor wafers produced using the semiconductor process;
receive input of the parametric electrical test attribute value data from the database of parametric electrical test attribute values for parametric electrical tests performed on the set of semiconductor wafers;
classify the yield value data into the inlier class and the outlier class;
assess one or more critical parametric electrical test attributes based on the inlier class and the outlier class of the yield value data and the parametric electrical test attribute value data;
assess one or more statistical process control thresholds corresponding to one or more of the critical parametric electrical test attributes, wherein the statistical process control thresholds are process control thresholds for the semiconductor process; and
generate the database of critical parametric electrical test parameters.
